(19) United States
(12) Patent Application Publication
(10) Pub. No.: US 2015/0061152 A1
(43) Pub. Date: Mar. 5, 2015

(54) PACKAGE MODULE WITH OFFSET STACK DEVICE

(71) Applicant: Innovative Turnkey Solution Corporation, Hsinchu City (TW)

(72) Inventor: Shih-Chi CHEN, Hsinchu City (TW)

(73) Assignee: Innovative Turnkey Solution Corporation, Hsinchu City (TW)

(21) Appl. No.: 14/088,915

(22) Filed: Nov. 25, 2013

(30) Foreign Application Priority Data
Aug. 28, 2013 (TW) 102130766

(51) Int. Cl. H01L 25/065; H01L 23/48

(52) U.S. Cl. CPC H01L 25/0657; H01L 23/481
USPC 257/774

(57) ABSTRACT

A package module with offset stacked device is provided which includes a group of stacked device, a carrier and a substrate. The group of stacked device is offset stacked to dispose in the carrier and the substrate is disposed on the bottom of the carrier. A plurality of electric connections is disposed on the surface substrate that is opposite to the carrier. A plurality of outer connections on another surface of the substrate is electrically connected with the plurality of electric connections. The group of the stacked device is electrically connected with the carrier by the connecting the plurality of metal connections and the pads. The plurality of metal connections is extended to the bottom of the carrier to form another metal connection to electrically connect with the electric connection on the substrate.

### FIELD OF THE INVENTION

The present invention relates to a package module with an offset stacked device, and in particular to a stacked packaging technology with three-dimensional carrier to form a package module.

### BACKGROUND OF THE INVENTION

Modern life is inseparable from the large number of electronic products, and therefore the demand for the semiconductor industry, more and more, the semiconductor industry will continue to evolve to meet the market demand for a variety products, the most common needs of hope is that the product with better functionality is manufactured by the smaller space the same or even better product functionality.

The stacked chip package is a package method for reducing the space of the package product, the package method arranges a number of different dies with different function into a package module, in addition to achieve functional integration purposes, the space of circuit board can effectively save, and the space occupied by the chip can also be reduced, so as to reduce overall manufacturing costs. In addition, the circuit distance between the plurality of dies in the package can be short to provide the better electrical performance, and the signal propagation is interfered in the circuit can be effectively reduced.

Currently, the stacked chip package is mostly memory chip package, such as flash memory and static random access memory are stacked each other. The part of the communications chip also utilizes the stacked wafer level package, for example, the base frequency, flash memory and static random access memory chips, which are configured into a single package.

However, the present stacked chip package has some drawbacks, such as a wafer are stacked in each other processes, because the chip includes a lots of pads thereon, so as to the electric contacts between the wafer substrate (substrate) and the substrate is difficult, and thus yield is to be reduced. Furthermore, in order to enhance the connection between the wafers, the most common way is to increase the encapsulation process between the wafers, however, the excessive encapsulation glue will increase the thickness of the overall packaging products, and the reliability of the package product is also reduced. In addition, also, it is difficult process to bonding the metal wires on the stacked wafers. In addition, when the packaged product is assembled to other electronic device such as circuit board, which needs the alignment to align the joint and the pads, such that the cost of packaging is to be increased. For the above disadvantages, there is a need for improvement.

### SUMMARY OF THE INVENTION

In order to solve the aforementioned drawbacks, the present invention provides a package module with an offset stacked device by the way of the three-dimensional carrier design to simply the stacked package device and to improve the reliability of the package product.

According to above object, the present invention provides a package module with an offset device which includes a carrier having a first surface and a second surface opposite to the first surface, a recess is formed on the first surface and an edge around the recess, the a first chip arrangement region is formed on the recess and a plurality of first metal connections is disposed on a bottom of the recess. A first platform is disposed adjacent to one side of the first chip arrangement region and the first metal connection is exposed. The first platform is higher than the first chip arrangement region. A plurality of second metal connections is disposed on the first platform, in which each the plurality of first metal connections is corresponding to one of the plurality of second metal connections, and the corresponded first metal connection is electrically connected with the second metal connection through a first metal wire. A first chip having a top and a bottom and a plurality of first pads is disposed on the bottom. The first chip is disposed on the first chip arrangement region such that the first pad is electrically connected with the first metal connection. A second chip having a top and a bottom and a plurality of second pads is disposed on the bottom, and the second chip is flipped on the top of the first chip such that the second pads is electrically connected with the second metal connection and the portion top of the first chip is exposed. A glue is filled in the recess of the carrier to encapsulate the top of the exposed first chip and the top of the second chip, in which each second metal connection is electrically connected with a plurality of second meta connections, and the second metal wire is extended to the second surface of the carrier from the first platform of the carrier to the edge. Each the plurality of second metal wires on one end of said edge is to form a plurality of metal connections

The present invention further provides a package module with an offset stacked device, which includes a carrier having a first surface and a second surface opposite to the first surface. A plurality of carrier through holes is passed through the first surface from the second surface. A recess is disposed on the first surface and an edge around the recess. A first chip arrangement region is disposed on the recess and a plurality of first metal connections is disposed on a bottom of the recess. A first platform is disposed adjacent to one side of the first chip arrangement region and the first metal connection is exposed. The first platform is higher than the first chip arrangement region. A plurality of second metal connections is disposed the first platform. A first chip having a top and a bottom and a plurality of first pads is disposed on the bottom. The first chip is flipped on the first chip arrangement region such that the first pad is electrically connected with the first metal connection. A second chip having a top and a bottom and a plurality of second pads is disposed on the bottom. The second chip is flipped on the top of the first chip such that the second pad is electrically connected with the second metal connection on the first platform and the top of the portion first chip is exposed. A glue is filled in the recess of the carrier to encapsulate the top of exposed first chip and the top of the second chip, in which the first metal connection and the second metal connection are extended to the second surface of the carrier from through the carrier through hole, and each the plurality of first metal connections and each the plurality of second metal connections on one end of second surface is to form a plurality of metal connections.

The present invention also provides a package module with an offset stacked device, which includes a carrier having a first surface and a second surface opposite to the first surface. A plurality of carrier through holes is passed through the first surface to the second surface. A recess is disposed on the first surface and an edge around the recess. A first chip arrangement region is disposed on the recess and a plurality of first metal connections is disposed on a bottom of the recess. A first platform is disposed adjacent to one side of the first chip arrangement region and the first metal connection is exposed. the first platform is higher than the first chip arrangement region. A plurality of second metal connections is disposed on the first platform, in which each the first metal connection is corresponding to one of the second metal connection and the corresponded first metal connection is electrically connected with the corresponded second metal connection through a metal wire. A first chip having a top and a bottom and a plurality of first pads is disposed on the bottom. The first chip is flipped on the first chip arrangement region such that first pad is electrically connected with the first metal connection. A second chip having a top and a bottom and a plurality of second pads on the bottom. The second is flipped on the top of the first chip such that the second pad is electrically connected with the second metal connection on the first platform and the top of portion first chip is exposed. A glue is filled in the recess of the carrier to encapsulate the top of exposed first chip and the top of the second chip, in which the first metal connection and the second metal connection are extended to the second surface of the carrier through the carrier through hole and each first metal connection and each second metal connection on one end of the second surface are to form a metal connection respectively.

The present invention provides a package module with an offset stacked device, which includes a carrier having a first surface and a second surface opposite to the first surface and a plurality of carrier through holes is passed through the first surface to the second surface. A recess is disposed on the recess and an edge around the recess. A first chip arrangement region is disposed on the recess and a plurality of first metal connections is disposed on a bottom of the recess. A first platform is disposed adjacent to one side of the first chip arrangement region and a first metal connection is exposed. The first platform is higher than the first chip arrangement region. A plurality of second metal connections is disposed on the first platform, in which each first metal connection is corresponding to one of the second metal connection and corresponded first metal connection is electrically connected with the corresponded second metal connection through a metal wire. A first chip having a top and a bottom and a plurality of first pads is disposed on the bottom. The first chip is disposed on the first chip arrangement region such that the first pad is electrically connected with the first metal connection. A second chip having a top and a bottom and a plurality of second pads is disposed on the bottom. The second chip is flipped on the top of the first chip such that the second pad is electrically connected with the second metal connection on the first platform and the top of portion first chip is exposed. A glue is filled in the recess of the carrier to encapsulate the top of exposed first chip and the top of the second chip, in which the first metal connection is extended to the second surface of the carrier through the carrier through hole and each first metal connection on one end of the second surface is to form a metal connection.

The present invention provides a package module with an offset stacked device, which includes a carrier having a first surface and a second surface opposite to the first surface and a plurality of carrier through holes is passed through the first surface to the second surface. A recess is disposed on the first surface and an edge around the recess. A first chip arrangement region and a controlling chip arrangement are disposed on the recess respectively, in which the first chip arrangement region is disposed around the controlling chip arrangement region and the height of the first chip arrangement region is higher than that of the controlling chip arrangement region. a plurality of first metal connection is disposed on the controlling chip arrangement and a plurality of second metal connections is disposed on the first chip arrangement region. A first platform is disposed adjacent to one side of the first chip arrangement region and a second metal connection is exposed. The first platform is higher than the first chip arrangement region. a plurality of third metal connections is disposed on the first platform. A controlling chip having a top and a bottom and a plurality of first pads is disposed on the bottom. The controlling chip is flipped on the controlling chip arrangement region, such that the first pad is electrically connected with the second pad, and the first chip is flipped on the first chip arrangement region to encapsulate the controlling chip such that the second pad is electrically connected with the second metal connection. A second chip having a top and a bottom and a plurality of third pads is disposed on the bottom. The second chip is flipped on the top of the first chip such that the third pad is electrically connected with the third metal connection on the first platform and the top of portion first chip is exposed. a glue is filled in the recess of the carrier to encapsulate the top of exposed first chip and the top of the second chip, in which the first metal connection, the second metal connection and the third metal connection are extended to the second surface of the carrier through the carrier through hole and each the first metal connection, each the second metal connection and each the third metal connection are disposed on one end of the second surface to form a metal connection respectively.

The present invention provides a package module with an offset stacked device, which includes a carrier having a first surface and a second surface opposite to the first surface, a recess is disposed on the first surface and an edge around the recess, a first chip arrangement region is disposed on the recess and a plurality of first metal connections is disposed on a bottom of the recess. A first platform is disposed adjacent to one side of the first chip arrangement region and the first metal connection is exposed. The first platform is higher than the first chip arrangement region and meanwhile, a first recess wall is disposed between the first platform and the first chip arrangement region. An angle is disposed between the first recess wall and the first chip arrangement region which is in range from 90 degree and 135 degree. A plurality of second metal connections is disposed on the first platform, in which each the first metal connection is corresponding to one of the second metal connection and corresponded first metal connection is electrically connected with the second metal connection through a first metal wire. The first metal wire is disposed on the first recess wall. A first chip having a top and a bottom and a plurality of first pads is disposed on the bottom of the first chip. The first chip is flipped on the first chip arrangement region such that the first pad is electrically connected with the first metal connection. A second chip having a top and a bottom and a plurality of second pads is disposed on the bottom of the second chip. The second chip is flipped on the top of the first chip such that the second pad is electrically connected with the second metal connection on the first platform and the top of the portion first chip is exposed. A glue is filled in the recess of the carrier to encapsulate the top of the first chip and the top of the second chip, in which each the plurality of second metal connections is electrically connected with a plurality of second metal wires, the plurality of second metal wires is extended to the second surface of the carrier from the first platform on the carrier through the second recess wall and the edge, and each the plurality of second metal wires on one end of the second surface is to form a metal connection.

According to the package module with an offset stacked device of the present invention, the stacked device module is combined with the carrier during the packaging process and further to combine the carrier with the substrate so as to the package module is accomplished, in which the carrier and the substrate can be performed via standardized process by other manufactures, such that the cost of the packaging can be decreased.

According to the package module with an offset stacked device of the present invention, the stacked components is disposed in the carrier after packaging process, such that the package module will not be affected by external substances, such that the reliability can be improved.

According to the package module with an offset stacked device of the present invention, the carrier and the substrate can be manufactured via the standardized process, such that the product size can also be standardized, and time required for the wire bonding and the alignment can be decreased, and the work efficiency for the packaged plant and the subsequent package application vendors can be increased.

### BRIEF DESCRIPTION OF THE DRAWINGS

The present invention will be apparent to those skilled in the art by reading the following description of a preferred embodiment thereof with reference to the drawings, in which:

FIG. 1 is a top view of the carrier in accordance with the present invention;

FIG. 2A is a top view of the carrier in accordance with the present invention;

FIG. 2B is a vertical view of carrier in accordance with the present invention;

FIG. 3 is a vertical of the first chip in accordance with the present invention;

FIG. 4A is a cross-sectional view of a first embodiment of a package module with an offset stacked device in accordance with the present invention;

FIG. 4B is a cross-sectional view of another embodiment of the package module with an offset stacked device in accordance with the present invention;

FIG. 5A is a top view of substrate in accordance with the present invention;

FIG. 5B is vertical view of the substrate in accordance with the present invention;

FIG. 6 is a cross-sectional view of the package module with an offset stacked device in accordance with the present invention;

FIG. 7A is a to view of the third embodiment of the carrier in accordance with the present invention;

FIG. 7B is a vertical view of the third embodiment of carrier in accordance with the present invention;

FIG. 8 is a top view of the third embodiment of the substrate in accordance with the present invention;

FIG. 9 is a cross-sectional view of third embodiment of the package module with an offset stacked device in accordance with the present invention;

FIG. 10A is a top view of the fourth embodiment of the carrier in accordance with the present invention;

FIG. 10B is a vertical view of the fourth embodiment of the carrier in accordance with the present invention;

FIG. 11 is a cross-sectional view of the fourth embodiment of the package module with an offset stacked device in accordance with the present invention;

FIG. 12A is a top view of the fifth embodiment of the carrier in accordance with the present invention;

FIG. 12B is a vertical view of the fifth embodiment of the carrier in accordance with the present invention;

FIG. 13 is a top view of the fifth embodiment of the substrate in accordance with the present invention;

FIG. 14 is a cross-sectional view of fifth embodiment of the package module with an offset stacked device in accordance with the present invention;

FIG. 15A is a top view of sixth embodiment of the carrier in accordance with the present invention;

FIG. 15B is a vertical view of sixth embodiment of the carrier in accordance with the present invention;

FIG. 16 is a cross-sectional view of sixth embodiment of the package module with an offset stacked device in accordance with the present invention;

### DETAILED DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

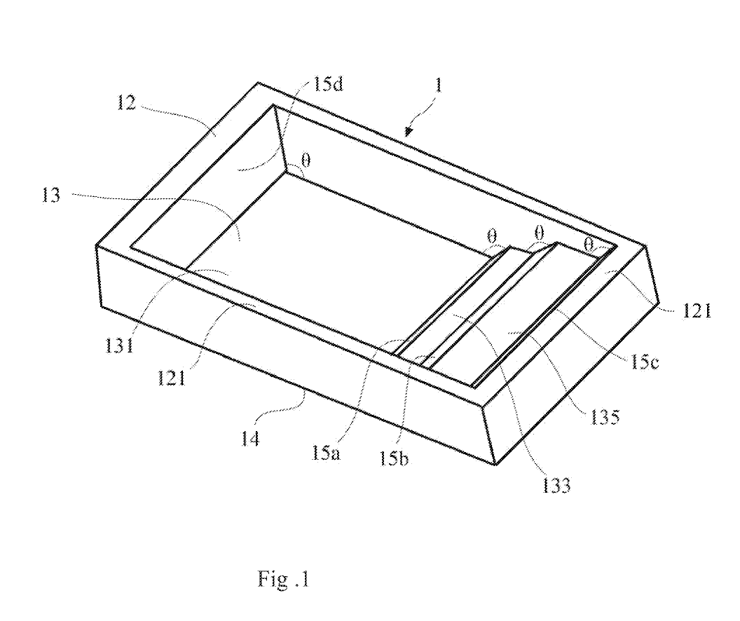

Please refer to FIG. 1. FIG. 1 is a top view of the carrier of the present invention. In FIG. 1, the carrier 1 is formed by polymer injection molding method, and the material of the polymer is polyimide ammonium. The carrier 1 having a first surface 12 and a second surface 14 opposite to the first surface. A recess 13 is disposed on the first surface 12 and an edge 121 around the recess 13. The bottom of the recess 13 is a first chip arrangement region 131. A first platform 133 and a second platform 135 are disposed on one side of the recess 13 respectively. The first platform 133 is disposed adjacent to the first chip arrangement region 131 and the height of the first platform 133 is higher than that of the first chip arrangement region 131. In one embodiment, the height of the first platform 133 can be designed as the same height of the chip which is to be packaged. Then, the second platform 135 is disposed adjacent to the first platform 133 and the height of the second platform 135 is higher than that of the first platform 133. In one embodiment, the height of the second platform 135 can be designed as same that of the chip which is to be packaged. According to aforementioned, the first chip arrangement region 131, the first platform 133 and the second platform 135 can be regards as a stepped structure on one side of the recess 13. In addition, the recess wall 15a between the first chip arrangement region 131 and the first platform 133, the recess wall 15b between the first platform 133 and the second platform 135, the recess wall 15c between the second platform 135 and the first surface 12, and the recess wall 15d between the first surface 12 and the first chip arrangement region 131 are inclined. The angle θ between each recess wall and each plane is denote as in which the angle θ is in range from 90 degree to 135 degree, 90≦θ≦135, that is, each recess wall 15a, 15b, 15c and 15d are either vertical or inclined. It is note to illustrate that the angle between each recess wall 15a, 15b, 15c, 15d and each plane of the recess is not to be limited. The purpose for disposing the recess wall 15a, 15b, 15c, and 15d is to assist the location and the alignment of the chip while the chip is being packaged onto the carrier 1.

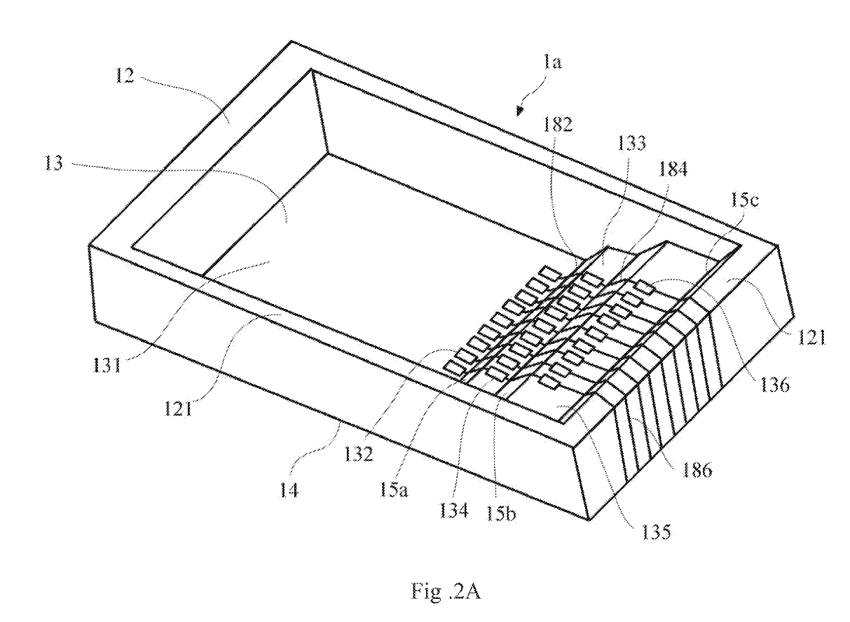

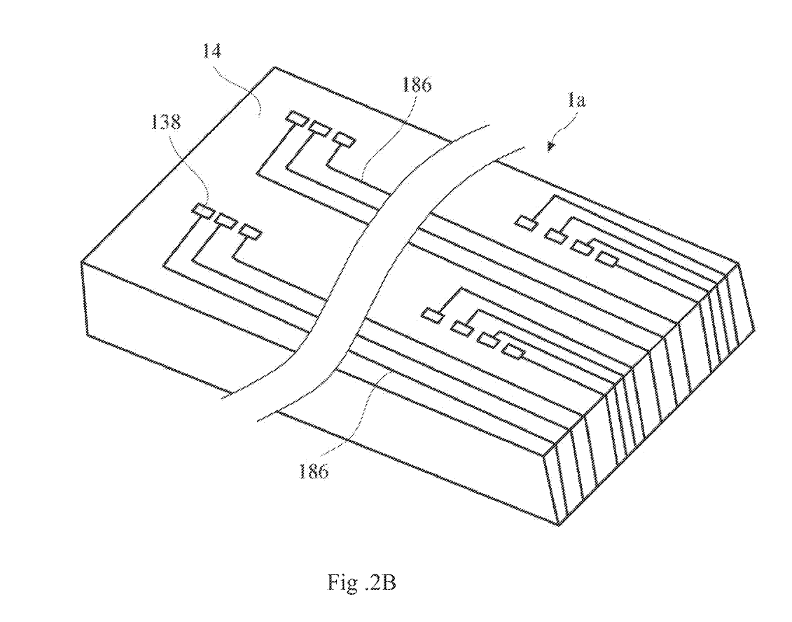

Next, please refer to FIG. 2A and FIG. 2B. FIG. 2A is a top view of the carrier and FIG. 2B is a vertical view of the carrier of the present invention. First, as shown in FIG. 2A, the carrier 1a is disposed in the first chip arrangement region 131 and a plurality of metal connections 132 is disposed adjacent to one side of the first platform 133. A plurality of metal connections 134 is disposed on the first platform 133 and a plurality of metal connections 136 is disposed on the second platform 135. Meanwhile, the number of each the plurality of metal connections 132 is equal to that of each the plurality of metal connection 134 and each the plurality of metal connections 136, and the locations of each the plurality of metal connections 132, each the plurality of metal connections 134 and each the plurality of metal connections 136 are corresponding to each other. In addition, each the plurality of metal connections 132 is electrically connected with each the plurality of metal connections 134 through the plurality of metal wires 184, and each the plurality of metal connections 136 is electrically connected with the plurality of metal wires 186, in which each the plurality of metal wires 186 is extended to the second surface 14 of the carrier 1a from the recess wall 15a and the edge 121 of the first surface 12 and the plurality of metal wires 186 is arranged on one end of each the plurality of metal wires 186 to form a metal connection 138, such that the plurality of metal connections 138 is formed in a row on the second surface 14 of the carrier 1a, and the plurality of metal connections 138 is formed in neatly arrangement as shown in FIG. 2B. However, the arrangement of the plurality of metal connections 138 and the plurality of metal s 186 on the second surface 14 is not to be limited, for example, the plurality of metal connections 138 is disposed adjacent to the peripheral of the second surface 14.

Then, the formation of the plurality of metal connections 182, 184, 186 includes the location of the plurality of metal wires 182, 184, 186 is first formed by laser engraving and then electroplating. For example, the recess wall 15a between the plurality of metal connections 132 and the plurality of metal connections 143 is engraved to form a location of plurality of metal wires 182 and then a plurality of metal wires 182 is formed by electroplating. In one embodiment, the recess wall 15a, 15b, and 15c are inclined such that electroplating of the plurality of metal wires 182, 184, and 186 can be effectively improved.

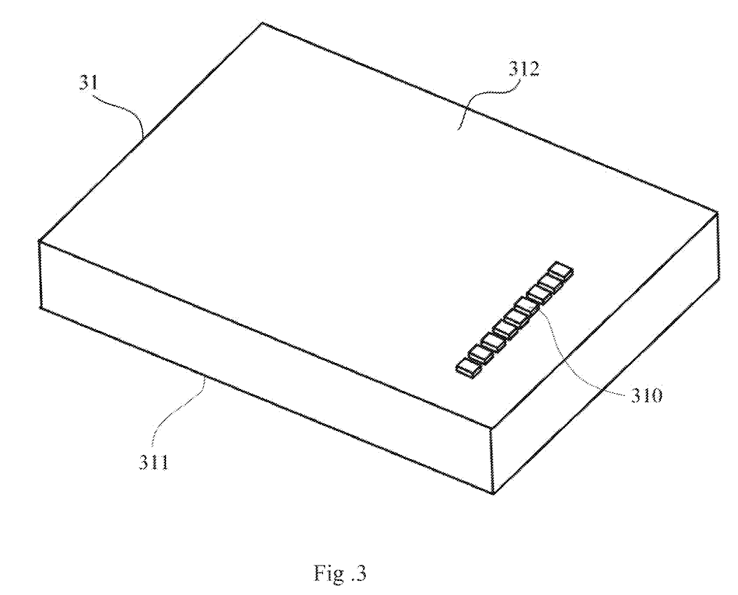

Next, please refer to FIG. 3. FIG. 3 is a vertical view of the first chip. As shown in FIG. 3, the first chip 31 is formed by cutting the wafer after accomplishing the semiconductor manufacturing. The first chip 31 having a top 311 and a bottom 312 opposite to the top 311. A plurality of pads is disposed on the bottom 312 of the first chip 31. In this invention, the first chip 31 can be a memory chip, in particular to a NAND flash memory. When the first chip 31 is NAND flash memory, there are 48 pads on the bottom 312 of the first chip 31. Oppositely, there are 48 metal connections 132, 48 metal connections 134, 48 metal connections 136 and 48 metal connections 138 are disposed in the carrier 1, and there will be a corresponding number of plurality of metal wires 182, 184 and 186, in which the each corresponding plurality of metal connections between the plurality of metal connections is electrically connected each other via the plurality of metal wires. However, the number of the pads on the first chip 31 is not to be limited, similarly, the number of the metal connections 132, 134, 136, 138 and the different number of the metal wires 182, 184, and 186 is corresponding to the different number of the pads 310.

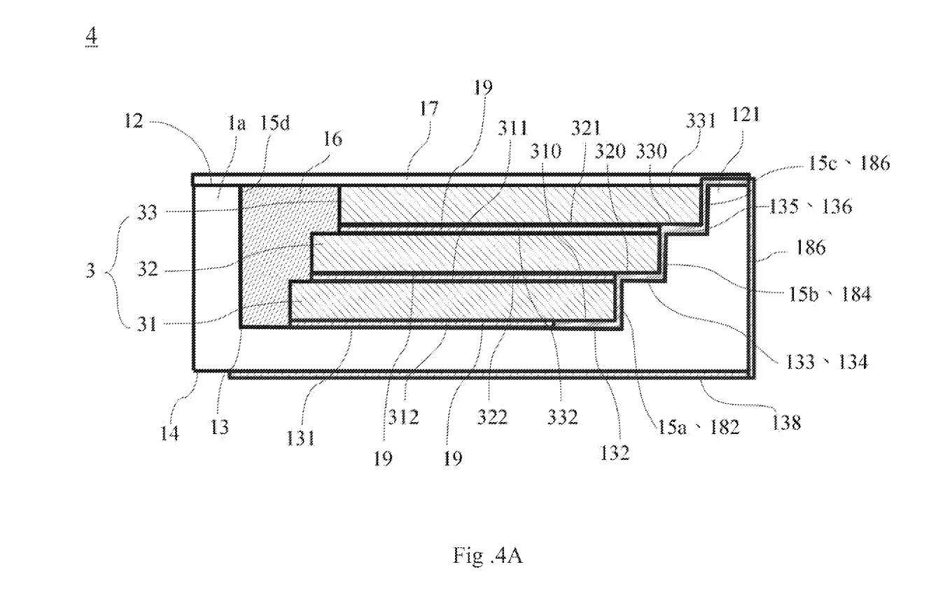

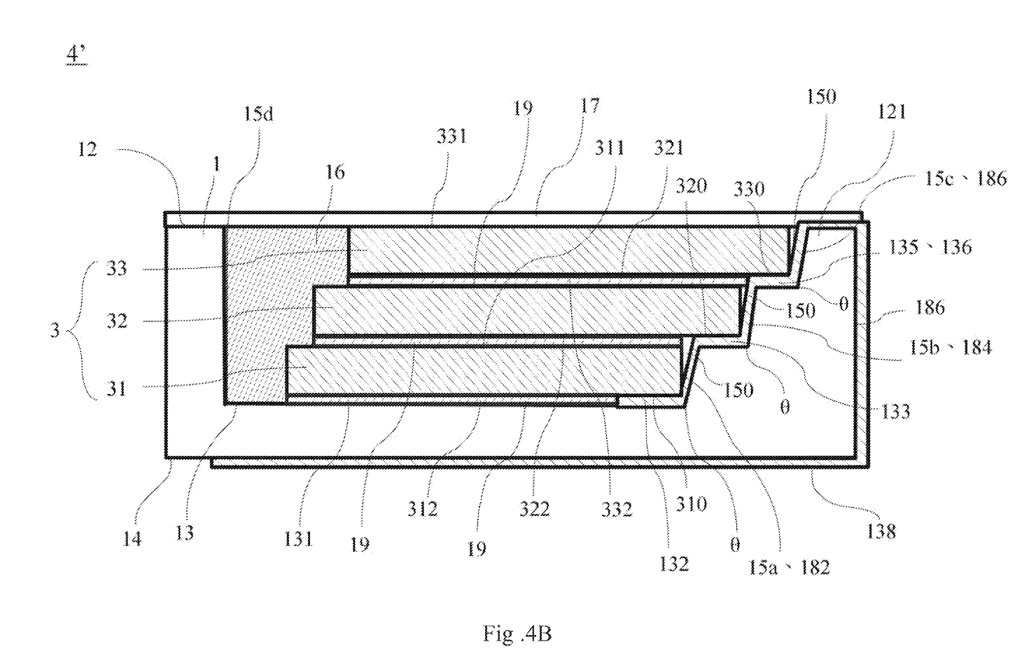

Next, please refer to FIG. 4A. FIG. 4A shows a cross-sectional view of a first embodiment of a package module with an offset stacked device of the present invention. As shown in FIG. 4A, the package module 4 with an offset stacked device includes a carrier 1a (as shown in FIG. 2A) and a group of stacked device 3. The group of stacked device 3 is constructed by a first chip 31, a second chip 32 and a third chip 33 that are stacked in the recess 13 of the carrier 1a, in which the profile of the second chip 32 and the third chip 33 is similar to the second chip 32, and thus it would not be described herein and the connecting relationship between the group of stacked device 3 and the recess 13 will be described in detail in subsequently specification.

First, a buffer material 19 is formed above the first chip arrangement region 131, and the first chip 31 is disposed in the first chip arrangement region 131, in which the plurality of pads 310 on the bottom of the first chip 31 is flipped and electrically connected with the plurality of metal connections 132, such that the buffer material 19 is disposed between the first chip 31 and the first chip arrangement region 131. The material of the buffer material 19 can be a paste. Then, a buffer material 19 is formed on the top 311 of the first chip 31 and the bottom 322 of the second chip 32 is flipped to contact the top 311 of the first chip 31, such that the plurality of pads 320 on the bottom 322 of the second chip 32 is electrically connected with the plurality of metal connections 134 on the first platform 133, and the buffer material 19 is disposed between the second chip 21 and the first chip 31. In addition, when the bottom 322 of the second chip 32 is stacked on the top 311 of the first chip 31, the portion top 311 of the first chip 31 is not encapsulated by the second chip 32. Next, the buffer material 19 is formed above the top 321 of the second chip 32 and the bottom 332 of the third chip 33 is flipped to contact the top 321 of the second chip 32, such that the plurality of pads 330 on the bottom 332 of the third chip 33 is electrically connected with the plurality of metal connections 136 on the second platform 135, and the buffer material 19 is disposed between the third chip 33 and the second chip 32. Furthermore, when the bottom 332 of the third chip 32 is stacked on the top 321 of the second chip 32, the portion top 321 of the second chip 32 is not to be covered by the third chip 33. Thus, when the plurality of chips is stacked in the carrier 1a, the plurality of chips will form a stepped structure on the opposite side of the first platform 133 and the second platform 135. In addition, it is emphasized that the height of the top 331 of the third chip 33 of the stacked device is not higher than that of the first surface 12 of the carrier 1a. As the abovementioned, the first chip 31, the second chip 32, and the third chip 33 is flipped and electrically connected with the carrier 1a. In addition, due to the recess wall 15a, recess wall 15b, and recess wall 15c are vertical as shown in FIG. 4, each chip is disposed close to the recess wall when the plurality of chip is packaged. After the plurality of chips is stacked to form a group of stacked device 3 in the carrier 1a, alternatively, a glue 16 is filled in the recess 13 of the carrier 1a, such that the glue 16 encapsulated the portion exposed top 311 of the first chip 31, the portion exposed top 321 of the second chip 32 and the top 331 of the third chip 33. In this embodiment, the glue 16 can be epoxy. In alternative embodiment, the glue film 17 is added on the first surface 12 of the carrier 1a such that the glue film 17 encapsulated the third chip 33, the edge 121 and the plurality of metal wires 186 on the edge 121.

Please refer to FIG. 4B. FIG. 4B shows a cross-sectional view of another embodiment of the package module with an offset stacked device of the present invention. In this embodiment, the recess wall 15a, recess wall 15b, and recess wall 15c can be designed as an inclined plan with an angle θ, that is, when the location of chip is disposed in recess 1a with slightly error, the each chip can slip to the suitable position via the inclined plane of recess wall 15a, recess wall 15b, and recess wall 15c. In addition, in one embodiment, the plurality of chips is stacked to form a group of stacked device 3 in the recess 13 of the carrier 1a, there is a gap 150 is formed between the each chips and the recess wall 15a, recess wall 15b, and recess wall 15c with the inclined plane. Then, a buffer material is optional to fill in the gap 150, such that the accommodate space is formed by the gap 150 can effective prevent the excess glue issue of the buffer material 18. In addition, alternatively, the glue 16 is filled in the recess 13 of the carrier 1a, such that glue 16 also encapsulated the portion exposed top 311 of the first chip 31, the portion exposed top 321 of the second chip 32 and the top 331 of the third chip 33. In this embodiment, the glue 16 can be an epoxy. Alternatively, the glue film 19 is added to form on the first surface of the carrier 1a to encapsulate the third chip 33, the edge 121 and the metal wire 186 on the edge 121 to achieve the protection of the group of stacked device 3 and the plurality of metal wires 186 effectively.

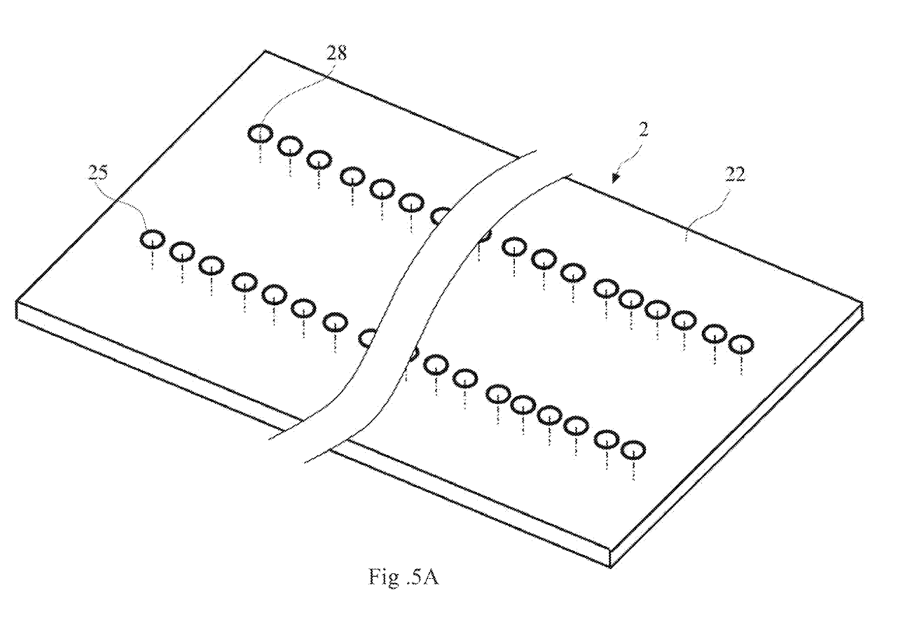

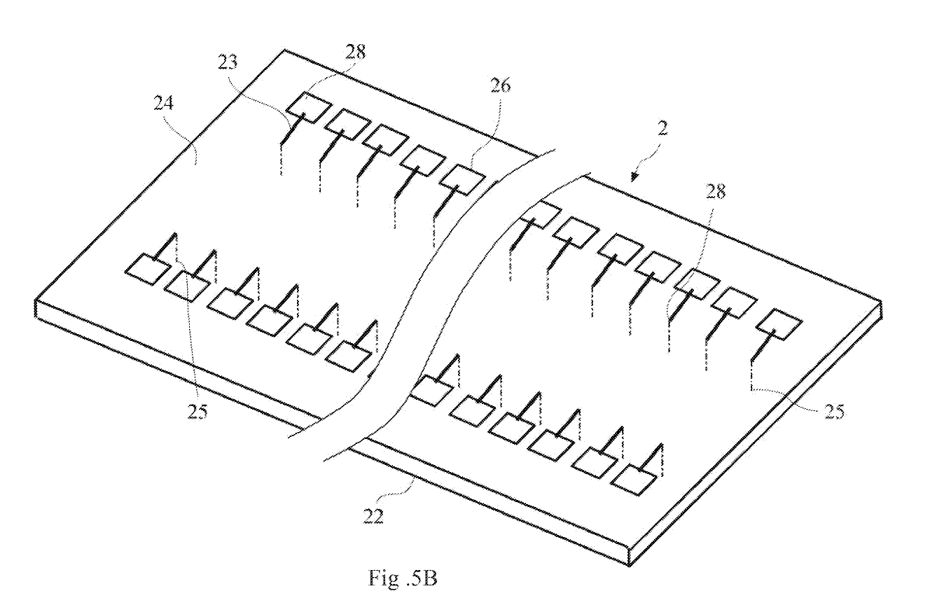

Next, please refer to FIG. 5A. FIG. 5A is a top view of substrate of the present invention. FIG. 5B is a vertical view of the substrate of the present invention. As shown in FIG. 5A, the substrate 2 having a third surface 22 and a fourth surface 24 opposite to the third surface 22, and a plurality of through holes 28 is extended to the fourth surface 24 from the third surface 22. A plurality of electric connections 25 is disposed on the third surface 22 and each the plurality of electric connections 25 is extended to the fourth surface 24 via the plurality of through hole 28 of the substrate 2 to form a plurality of outer connections 26. In addition, in one embodiment, the plurality of outer connections 26 on the fourth surface 24 can be configured via a plurality of metal wires 23 that is formed in a fan out configuration so as to the plurality of outer connections 26 is disposed on the peripheral of the fourth surface 24 of the substrate 2 and the distance and the size between the plurality of outer connections can be increased.

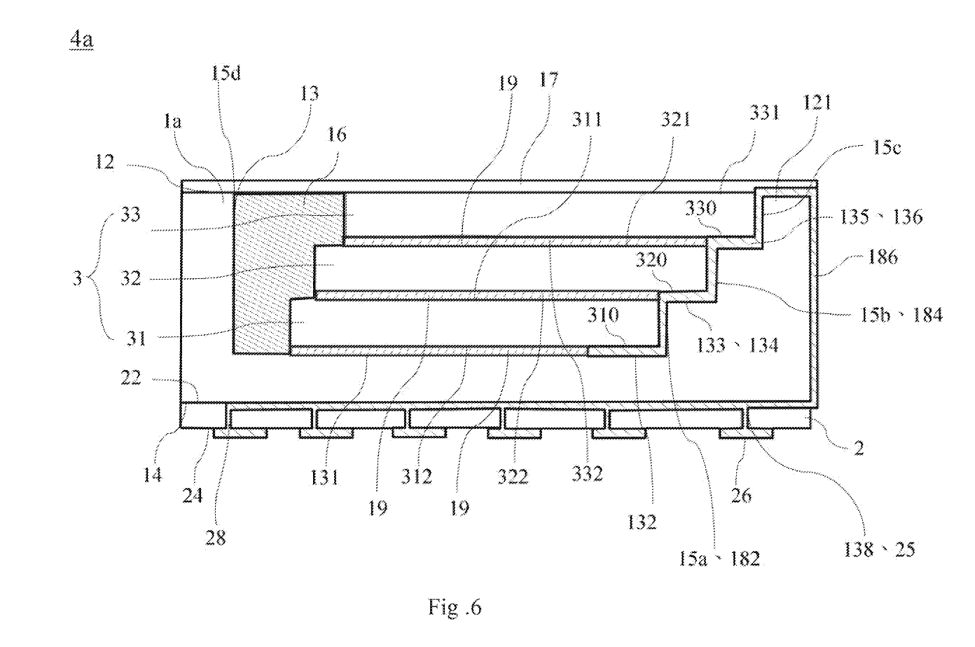

Please refer to FIG. 6. FIG. 6 is a cross-sectional view of the package module with an offset stacked device having a substrate of the present invention. As shown in FIG. 6, the second surface 14 of the carrier 1a of the package module with an offset stacked device is contacted the third surface 22 of the substrate 2 which is to form a package module 4a with an offset stacked device, in which the junction between the second surface 14 of the carrier 1a and the third surface 22 of the substrate 2 is formed by each the plurality of metal connections 138 is electrically connected with the plurality of electric connections 25 such that each the plurality of metal connections 138 on the second surface 14 of the carrier 1a is electrically connected with the plurality of outer connections 26 on the fourth surface 24 of the substrate 2. Obviously, to compare with the package module 4a with an offset stacked device, the package module 4 with an offset stacked device did not include substrate 2, for the package module 4 with an offset stacked device, the plurality of metal connections 138 on the second surface 14 of the carrier 1a is electrically connected with the connection (not shown) on another board (not shown). Obviously, the connection on another board is corresponding to the plurality of metal connections 138. In this embodiment, the recess wall 15a, recess wall 15b, and recess wall 15c are vertical respectively, and in other embodiment, the recess wall 15a, recess wall 15b and recess wall 15c are inclined, the advantages as described in paragraph [0047], and it is not to be described herein. In addition, when the plurality of metal connections 138 of the package module 4 with an offset stacked device is electrically connected with the connections (not shown) which is different from the substrate (not shown) with the plurality of metal connections 13, the plurality of metal connections 138 on the second surface 14 of the carrier 1a will need various configurations, such that the carrier 1a cannot performed module production to increase the manufacturing cost. For the package module 4a with an offset stacked device, to change fan out configuration of the plurality of outer connections 26 of the substrate 2, the package module 4a can able to cooperate with the various connection (not shown) such that the carrier 1a can be performed the module production and the package process cost can be decreased. Moreover, the carrier 1a can be packaged following above steps without the second platform 135. In other words, the structures of the package module 4, 4a with an offset stacked device can be different from the package modules shown in the FIG. 4A and FIG. 6 and the above advantages of the present invention are not to be affected.

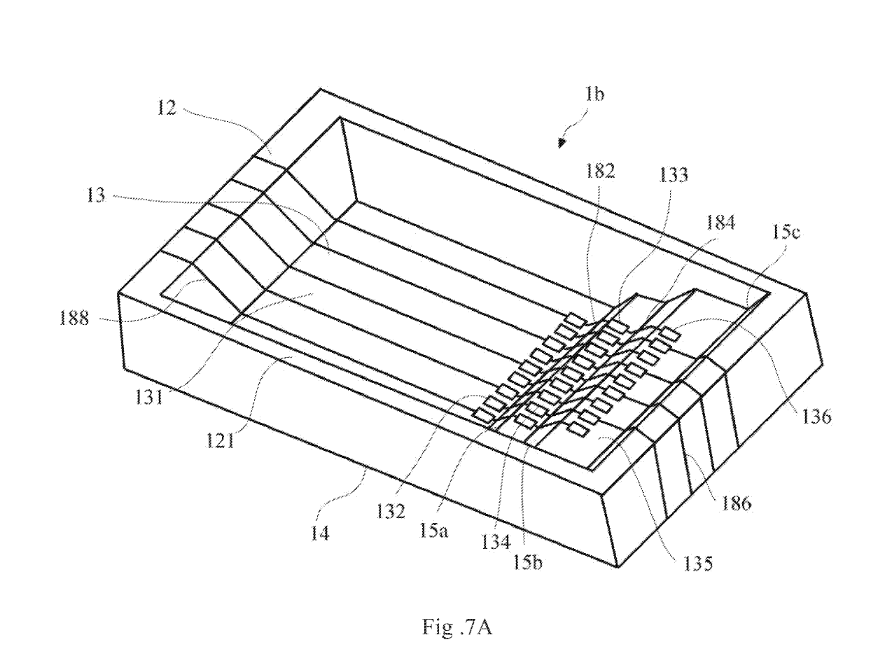

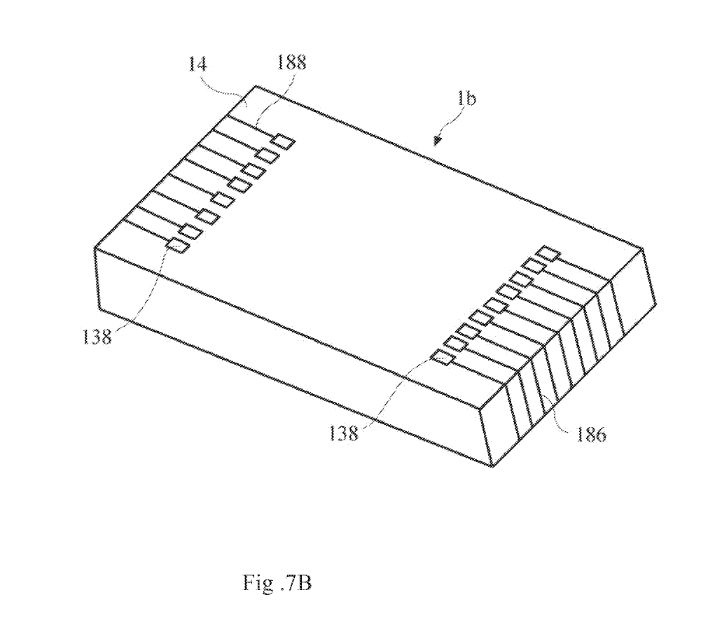

Then, please refer to FIG. 7A and FIG. 7B. FIG. 7A and FIG. 7B are the top view of carrier and the vertical view of the third embodiment of carrier of the present invention. As shown in FIG. 7A, a plurality of metal connections 132 is disposed to the first chip arrangement region 131 of the carrier 1b and is adjacent to one side of the first platform 133. A plurality of metal connections 134 is disposed on the first platform 133 and a plurality of metal connections 136 is disposed on the second platform 135. The number of each the plurality of metal connections 134 is identical to that of each the plurality of metal connection 136 and the location of each the plurality of metal connections 134 is corresponding to that of each the plurality of metal connections 136. In addition, each the plurality of metal connections 132 is electrically connected with each the plurality of metal connections 134 through the plurality of metal wires 182 and each the plurality of metal connections 134 is electrically connected with each the plurality of metal connections 136 through the metal wire 184, in which portion of the plurality of metal connections 132 is further electrically connected with the plurality of metal wires 188. The plurality of metal wires 188 is extended to the second surface 14 of the carrier 1b from the first chip arrangement region 131, the recess wall 15d and the edge 121 of the carrier 1b. The other portion of the plurality of metal connections 136 is not electrically connected with the plurality of metal connections 132 and is further electrically connected with the plurality of metal wires 186, in which the plurality of metal wires 186 is extended to the second surface 14 of the carrier 1b from the second platform 135 through the recess wall 15 and the edge 121 of carrier 1b, and the plurality of metal connections 186 and the plurality of metal wires 188 arranged on one end of each the plurality of metal wires 186 and each the plurality of metal wires 188 to form a metal connection 138, such that a plurality of metal connections 138 is arranged on the second surface 14 of the carrier 1b as shown in FIG. 7B. However, the arrangement for the plurality of metal connections 138, the plurality of metal wires 186 and 188 are not limited in this invention. For example, the plurality of metal connections 138 is disposed on the peripheral of the second surface 14. In this embodiment, each the plurality of metal wires 186 has a greater distances therebetween and thus, the manufacturing is relatively easy, and the configuration of the plurality of metal wire 188 has the same advantage as that of the plurality of metal wires 186.

The formation of the plurality of metal wires 182, the plurality of metal wires 184, and the plurality of metal wires 186 are similar to FIG. 2 and it is not described herein. In one embodiment, because of the recess wall 15a, recess wall 15b, recess wall 15c, and recess wall 15d are inclined, the plurality of metal wires 182, the plurality of metal wires 184, the plurality of metal wires 186, and the plurality of metal wires 188 can electroplate thereon easily, so that it can improve the package process yield and reliability of packaging module.

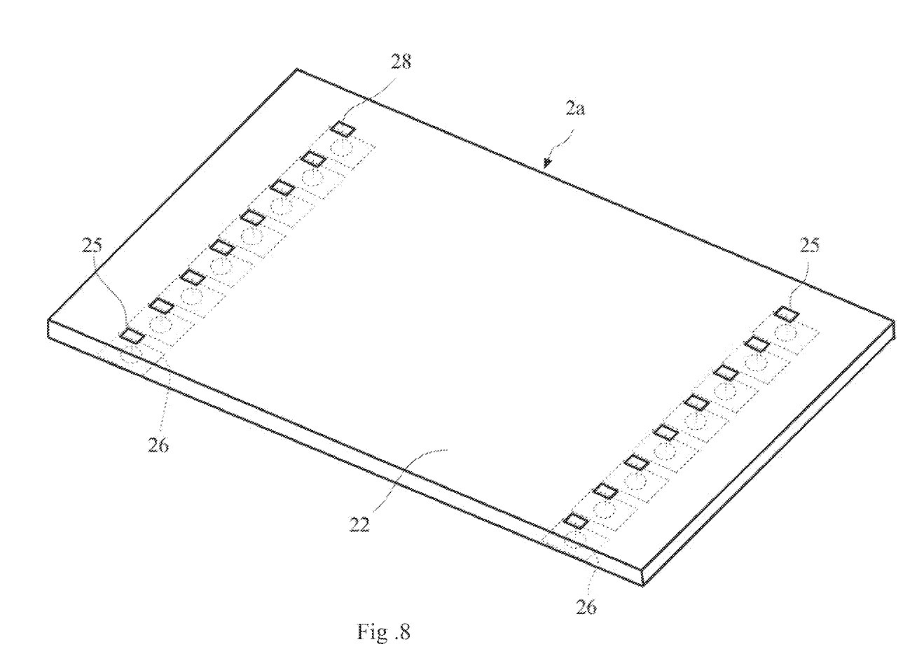

Then, please refer to FIG. 8. FIG. 8 is a top view of the third embodiment of the substrate of the present invention. As shown in FIG. 8, the substrate 2a having a third surface 22 and a fourth surface 24 opposite to the third surface 22 and a plurality of through holes 28 is passed through the third surface 22 to the fourth surface 24. A plurality of electric connections 25 is disposed on the third surface 22 and is extended to the fourth surface 24 along the plurality of through holes 28 to form a plurality of outer connections 26. The different from the substrate 2 is that the arrangement for the plurality of electric connections 25 on the substrate 2a and the plurality of outer connections 26 as shown in FIG. 7B. The arrangement of the plurality of metal connections 138 on the second surface 14 of the carrier 1b to make the plurality of electric connections 25 and the plurality of outer connections 28 in neatly arrangement as shown in FIG. 8.

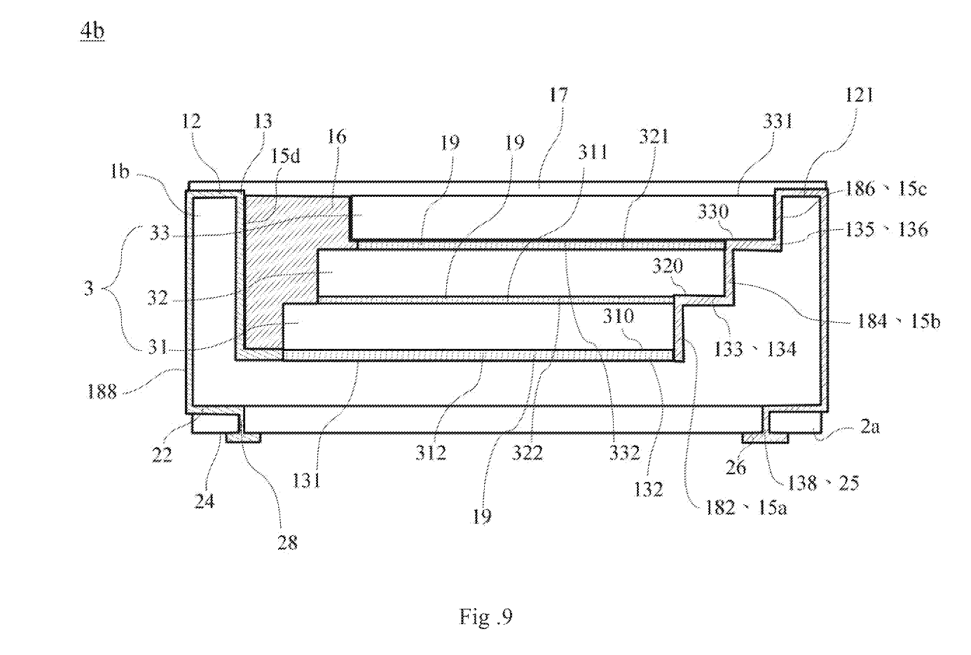

Please refer to FIG. 9. FIG. 9 is a cross-sectional view of third embodiment of the package module with an offset stacked device of the present invention. As shown in FIG. 9, the package module 4b with an offset stacked device includes a carrier 1b (as shown in FIG. 7A and FIG. 7B) and a substrate 2a and a group of stacked device 3 (as shown in FIG. 8). For the package module 4b with an offset stacked device, the configuration of the group of stacked device 3 is similar to the package module 4 with an offset stacked device in FIG. 4, and thus it is not to be described herein. In this embodiment, the recess wall 15a, recess wall 15b, and recess wall 15c are vertical or inclined in other embodiment. The advantage of the recess wall 15a, recess wall 15b and recess wall 15c as described in paragraph [0024]. The third surface 22 of the substrate 2 is contacted the second surface 14 of the carrier 1b and the plurality of the electric connections 25 on the third surface 22 is electrically connected with each the plurality of metal connections 138 on the second surface 14 of the carrier 1b. Otherwise, the substrate 2 is not need to install into the package module 4b with an offset stacked device to form another package module configuration. Moreover, the carrier 1b can be packaged following above steps without the second platform 135. In other words, the structures of the package module 4b with an offset stacked device can be different from the package module shown in FIG. 8 and the above advantages of the present invention are not to be affected.

According to above package modules 4, 4′, 4a, 4b with an offset stacked devices after packaging process, the package modules 4, 4′, 4a, 4b is electrically connected with the connection (not shown) on the other board (not shown) through the plurality of metal connections 138 or the plurality of outer connections 26. Because the plurality of metal wires 186 or the plurality of metal wires 188 is exposed outside the package modules 4, 4′, 4a, 4b with an offset stacked device, such that the package modules 4, 4′, 4a, 4b with an offset stacked device is electrically connected with the connection (not shown) on the other board (not shown), such that the short circuit can be reduced that is caused by the failure and the transmission efficiency of the circuit can be increased.

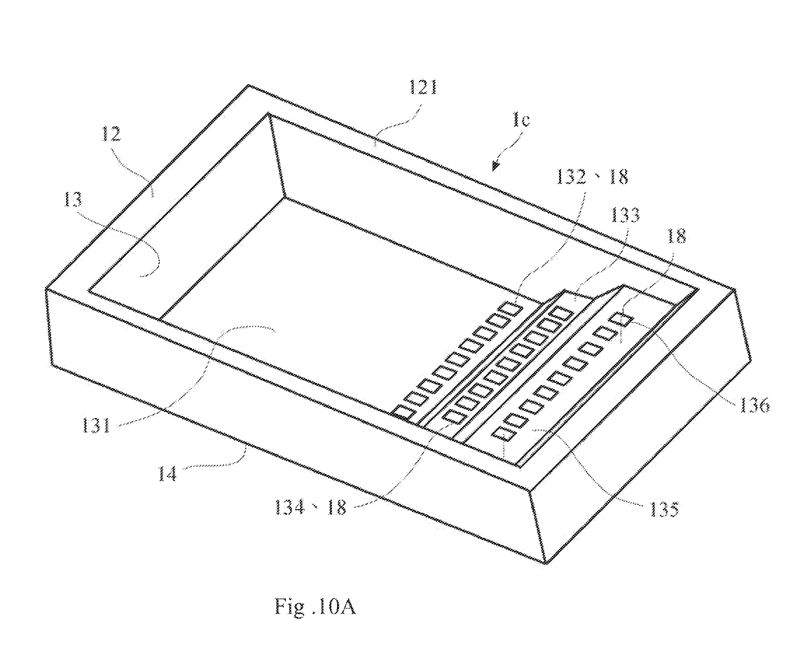

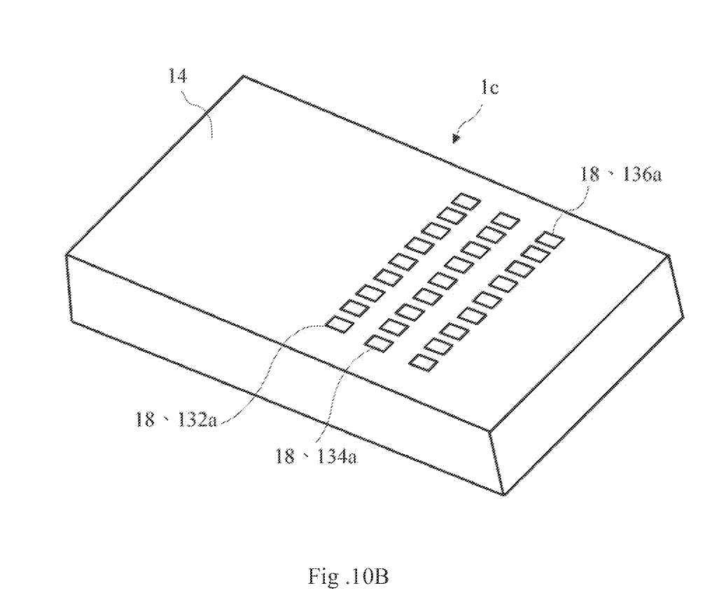

Please refer to FIG. 10A and FIG. 10B. FIG. 10A is a top view of the fourth embodiment of the carrier of the present invention and FIG. 10B is a vertical view of the fourth embodiment of the carrier of the present invention. As shown in FIG. 10A, a plurality of carrier through holes 18 is disposed on the first surface 12 of the carrier 1c and is passed through the second surface 14 of the carrier 1c. A plurality of metal connections 132 is disposed on the first chip arrangement region 131 and each the plurality of metal connections 132 is extended to the second surface 14 of the carrier 1c along the plurality of carrier through holes 18. A plurality of metal connections 134 is disposed on the first platform 133 and a plurality of metal connections 136 is disposed on the second platform 135. Each the plurality of metal connections 134, 136 are extended to the second surface 14 along the plurality of carrier through holes 18 to form a plurality of metal connections 132a, 134a, 136a respectively and the arrangement of the plurality of metal connections 132a, 134a, 136a as shown in FIG. 10B. In addition, the arrangement of the plurality of metal connections 132a, 134a, 136a on the second surface 14 are not limited herein.

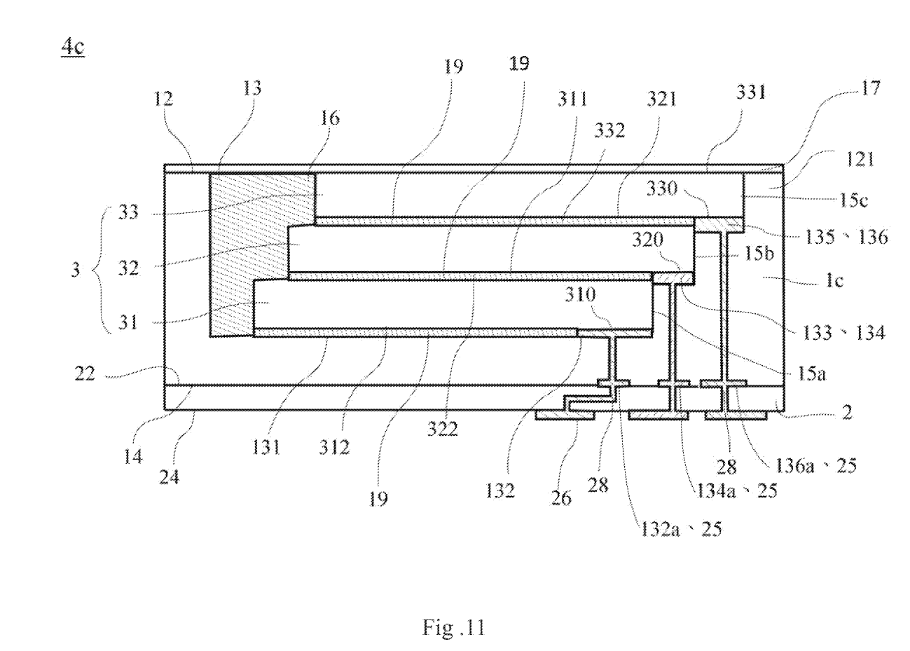

Please refer to FIG. 11. FIG. 11 is a cross-sectional view of the fourth embodiment of the package module with an offset stacked device of the present invention. As shown in FIG. 11, the package module 4c with an offset stacked device includes the carrier 1c in FIG. 10A and FIG. 10B, the substrate 2a and the group of the stacked device 3 in FIG. 8. For the package module 4c with an offset stacked device, the second surface 14 of the carrier 1c is contacted the third surface 22 of the substrate 22. The location of the plurality of metal connections 132a, 134a, 136a on the second surface 14 of the carrier 1c is opposite and electrically connected with the plurality of electric connections 25 on the third surface 12 of the substrate 2a. The group of the stacked device 3 and the glue 16 are disposed in the recess 13 respectively and the arrangement on the recess 13 is shown in FIG. 4A. In this embodiment, a glue film 17 is further disposed on the first surface 12 of the carrier 1c to encapsulate the recess 13 and the first surface 12. In this embodiment, the recess walls 15a, 15b, 15c are vertical and are inclined in other embodiments. The advantage of the recess walls 15a, 15b and 15c as described in paragraph [0047]. For the package module 4c with an offset stacked device, the plurality of outer connections 26 on the fourth surface 24 on the substrate 2 is electrically connected with the connections (not shown) on the board (not shown). Otherwise, the substrate 2 is not need to install into the package module 4c with an offset stacked device to form another package module, and the plurality of metal connections 132a, 132b, 132c are used as the connection which is electrically connected with the connections (not shown) on the board (not shown). Moreover, the carrier 1c can be packaged following above steps without the second platform 135. In other words, the structures of the package module 4c with an offset stacked device can be different from the package module shown in FIG. 11 and the above advantages of the present invention are not to be affected.

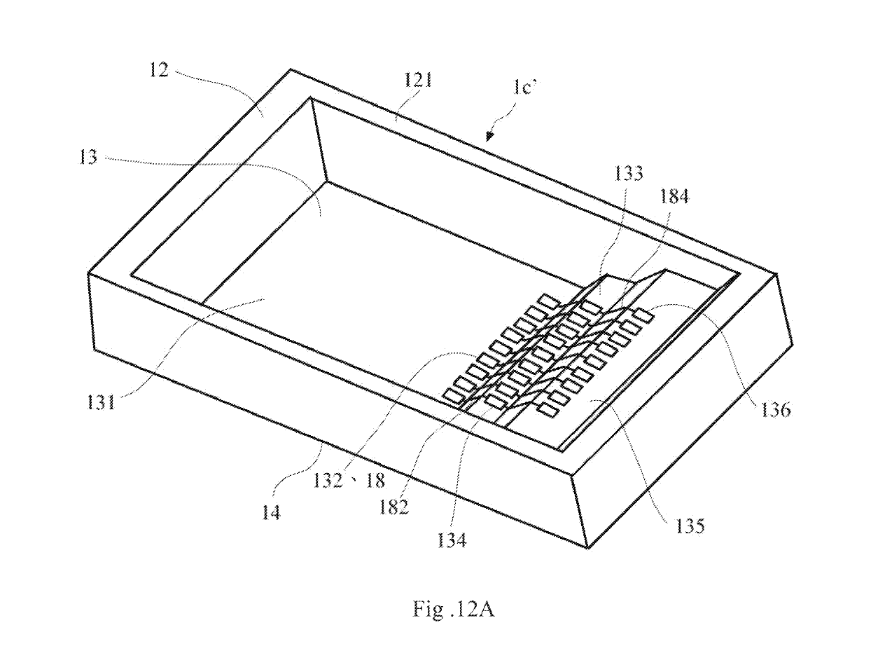

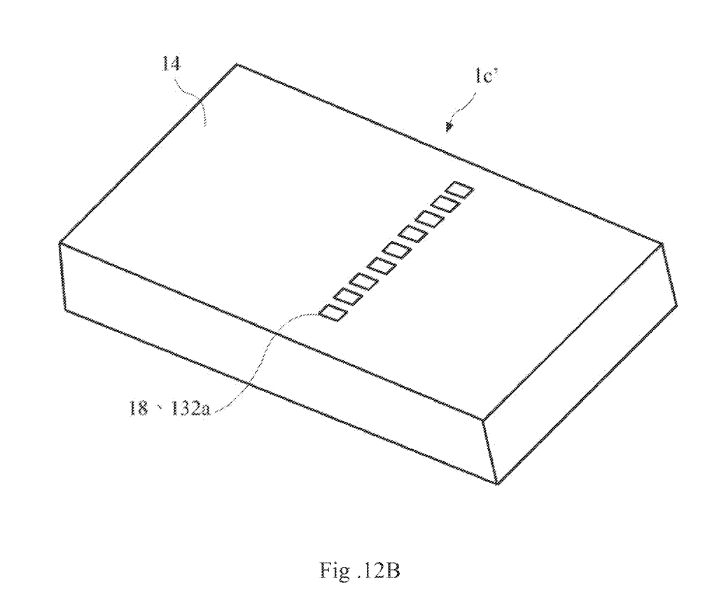

Please refer to FIG. 12A and FIG. 12B. FIG. 12A is a top view of the fifth embodiment of the carrier of the present invention and FIG. 12B is a vertical view of the fifth embodiment of the carrier of the present invention. As shown in FIG. 12A, the carrier 1c′ is different the carrier 1c in the FIG. 10A and FIG. 10B is that each the plurality of metal connections 132 on the first chip arrangement region 131 is electrically connected with a plurality of metal connections 134 on the first platform 133 through the plurality of metal wire 182. Each the plurality of metal connections 134 is electrically connected with the plurality of metal connections 136 on the second platform 135 through the plurality of metal wires 184. In addition, amount the plurality of metal connections 132, 134, 136, the plurality of metal connections 132 is extended to the second surface 14 on the carrier 1c through the plurality of carrier through holes 18 to form a plurality of metal connections 132a in arranged as shown in FIG. 12B. In addition, other structure and the arrangement of the carrier 1c′ are similar to the carrier 1c and it is not to be described herein.

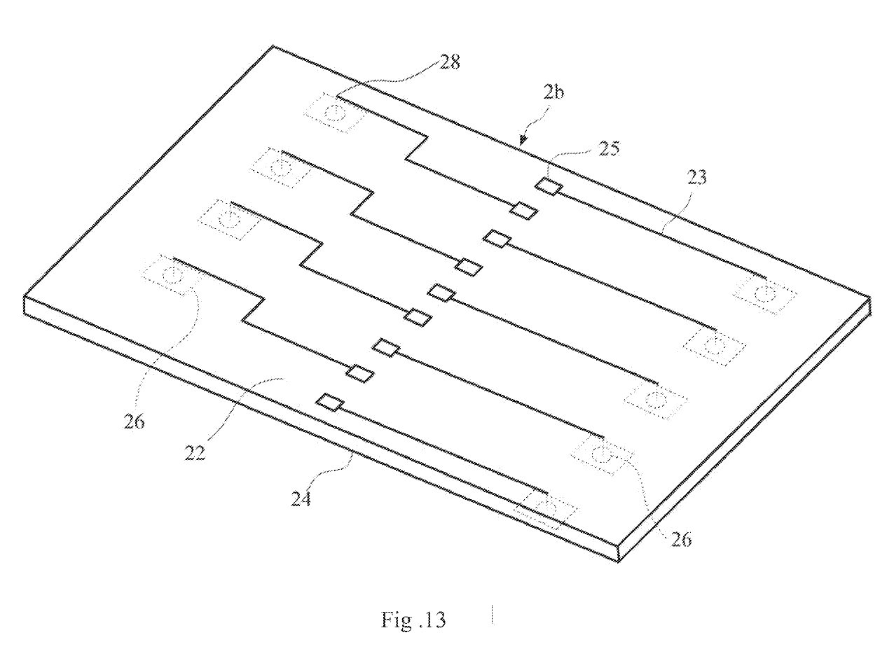

Please refer to FIG. 13. FIG. 13 is a top view of the fifth embodiment of the substrate. As shown in FIG. 13, the substrate 2b having a third surface 22 and a fourth surface 24 opposite to the third surface 22 The plurality of through holes is passed through the third surface 22 to the fourth surface 24, and the plurality of electric connections 25 is disposed neatly on the third surface 22, in which the arrangement of the plurality of electric connections 25 is corresponding to the plurality of metal connections 132a on the second surface 14 of the carrier 1c′ as shown in FIG. 12B. each the plurality of electric connections 25 is electrically connected with each the plurality of metal wires 23, and the plurality of metal wires 23 is fanned out toward the two sides of the third surface 22 and is extended to the fourth surface 24 through the plurality of through holes 28. Each the plurality of metal wires 23 is extended to the fourth surface 24 to form an outer connection 26. The outer connection 26 is arranged on two sides of the fourth surface 24 of the substrate 2b as shown in FIG. 13.

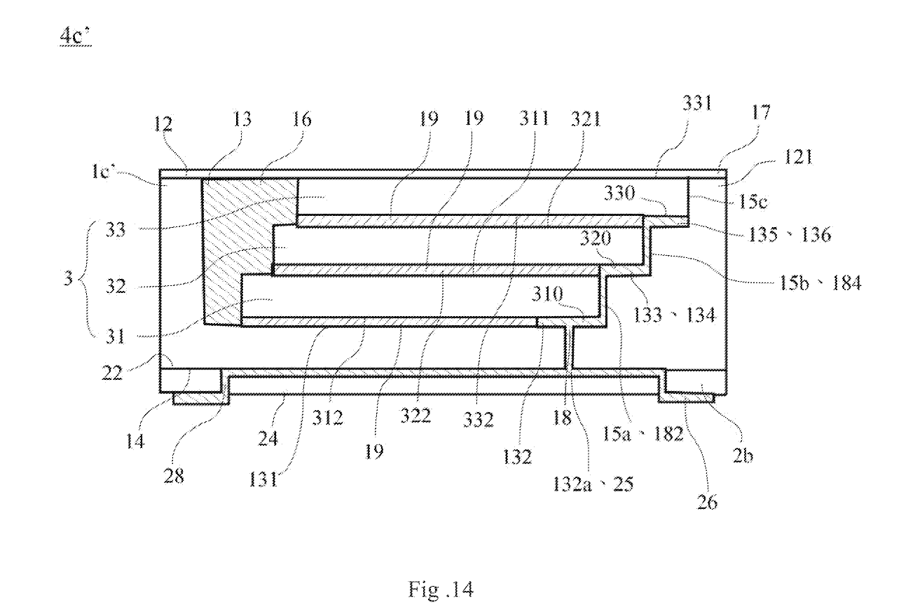

Please refer to FIG. 14. FIG. 14 is a cross-sectional view of fifth embodiment of the package module with an offset stacked device of the present invention. As shown in FIG. 14, the package module 4c′ with an offset stacked device includes a carrier 1c′ in FIG. 12A and FIG. 12B, and the substrate 2b and the group of stacked device 3 in FIG. 13. To compare the package module 4c′ with an offset stacked device with the package module 4c with an offset stacked device, in addition to the carrier 1c′ is different from the carrier 1c and the substrate 2b is different substrate 2, the structure and the arrangement for the package module 4c′ with an offset stacked device is identical to the package module 4c with an offset stacked device, and it is not to be described herein. The package module 4c′ with an offset stacked device utilizes the plurality of outer connections 26 on the fourth surface 24 of the substrate 2b to electrically connect with the connection (not shown) on the board (not shown). In this embodiment, the recess walls 15a, 15b and 15c are vertical and are inclined in other embodiment and the advantage of the recess walls 15a, 15b, and 15c as described in paragraph [0047]. In addition, the package module 4c′ with an offset stacked device did not add the substrate 2b so as to form another package module and the plurality of metal connections 132a as the contact that is electrically connected with the connection (not shown) on the board (not shown). Moreover, the carrier 1c′ can be packaged following above steps without the second platform 135. In other words, the structures of the package module 4c′ with an offset stacked device can be different from the package module shown in FIG. 14 and the above advantages of the present invention are not to be affected.

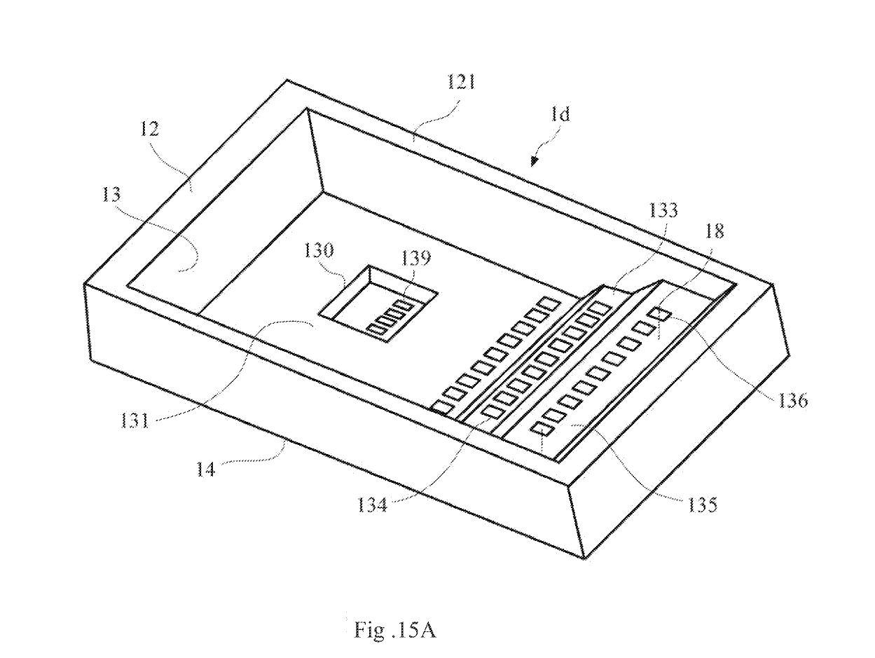

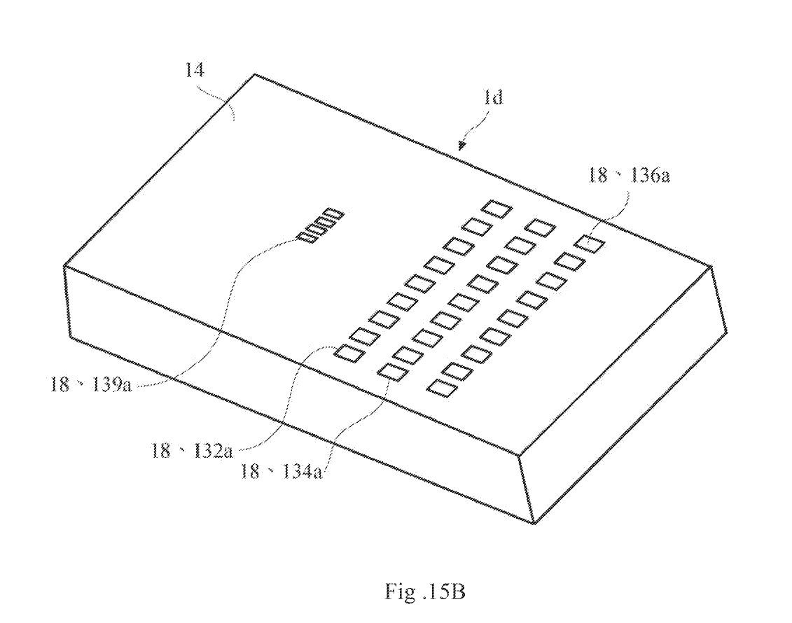

Please refer to FIG. 15A and FIG. 15B. FIG. 15A is a top view of sixth embodiment of the carrier of the present invention and FIG. 15B is a vertical view of sixth embodiment of the carrier of the present invention. As shown in FIG. 15A, the different between the carrier 1d and the carrier 1c in FIG. 10A and FIG. 10B is that another recess 130 is disposed in the recess 13. A controlling chip arrangement region 137 is further disposed in the recess 130. The first chip arrangement region 131 is disposed on the periphery of the controlling chip arrangement region 137 and the height of the controlling chip arrangement region 137 is lower than that of the first chip arrangement region 131. In one embodiment, the height of the controlling chip arrangement region 137 can be designed as the same that of the chip which is ready to place therein. A plurality of metal connections 139 is disposed on the controlling chip arrangement region 137 and each the plurality of metal connections 139 is extended to the second surface 14 of the carrier 1d along the plurality of carrier through holes 18 to form a plurality of metal connections 139 in neatly arrangement. The plurality of metal connections 132a, 134a, and 136a is disposed on the second surface 14 of the carrier 1d in neatly arrangement as shown in FIG. 12B. The other structure of the carrier 1d is identical to the carrier 1c in FIG. 10A and FIG. 10B and it is not to be described herein.

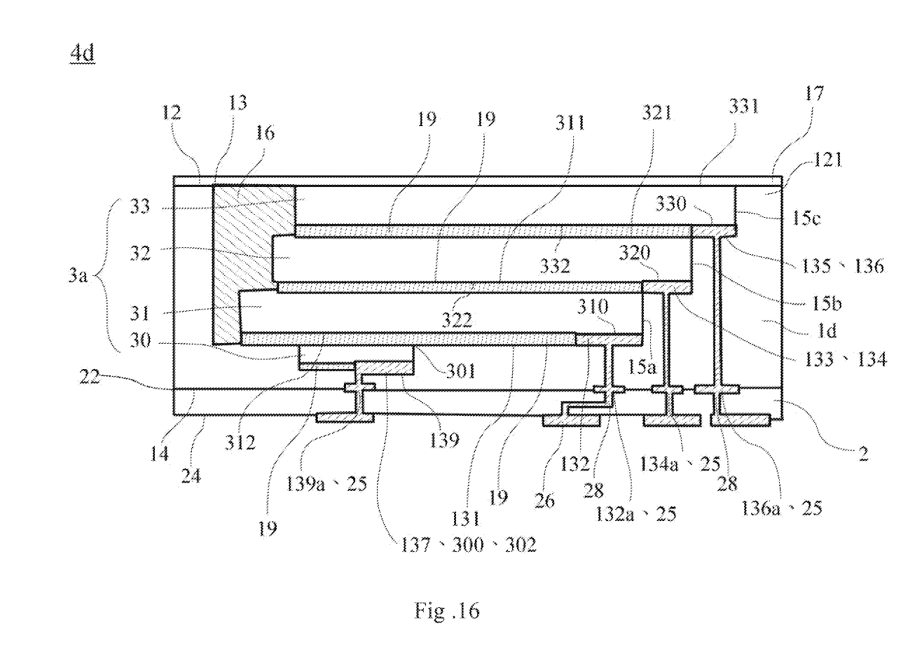

Please refer to FIG. 16. FIG. 16 is a cross-sectional view of the sixth embodiment of the package module with an offset stacked device of the present invention. As shown in FIG. 16, package module 4d with an offset stacked device includes carrier 1d in FIG. 15A and FIG. 15B and the substrate 2 and the group of stacked device 3a in FIG. 2. The group of the stacked device 3a includes a controlling chip 30, a first chip 31, a second chip 32 and a third chip 33, in which the profile of the controlling chip 30 is similar to the first chip 31 in FIG. 3. First, a buffer material 19 is formed above the controlling chip arrangement region 137 and the controlling chip 30 is flipped on the controlling chip arrangement region 137 such that the plurality of pads 300 on the bottom 302 of the controlling chip 30 is electrically connected with the plurality of metal connections 139 on the controlling chip arrangement region 137 and the buffer material 19 is disposed between the controlling chip 30 and the controlling chip arrangement region 137. The arrangement of other chips is similar to the package module 4 with an offset stacked device in FIG. 4 and it is not to be described herein. In addition, the first chip 31 on the first chip arrangement region 131 will encapsulate the top of the controlling chip 30 completely, the third surface 22 of the substrate 2 is connected the second surface 14 of the carrier 1d, and the plurality of metal connections 139a is opposite and electrically connected with the plurality of metal connections 25 on the third surface 22 of the substrate 22. The arrangement for the other structure of the first chip 31, the second chip 32, the third chip 33 and the package module 4d with an offset stacked device are similar to the package module 4c with an offset stacked device and it is not to be described herein. For the package module 4d with an offset stacked device, the plurality of outer connections 26 on the fourth surface 24 of the substrate 2 is electrically connected with the connection (not shown) on the board (not shown). In this embodiment, the recess walls 15a, 15b, 15c are vertical or inclined in other embodiments, and the advantage of the recess walls 15a, 15b, and 15c as described in paragraph [0047] In addition, the package module 4c′ with an offset stacked device did not add the substrate 2b so as to form another package module and the plurality of metal connections 132a, 134a, 136a and 139a as the contact that is electrically connected with the connection (not shown) on the board (not shown). Moreover, the carrier 1d can be packaged following above steps without the second platform 135. In other words, the structures of the package module 4d with an offset stacked device can be different from the package module shown in FIG. 16 and the above advantages of the present invention are not to be affected.

The number of the platform on the carriers 1, 1a, 1b, 1c, 1c′, 1d of the present invention is not limited, that is, in addition to the first platform 133 and the second platform 135, the carriers 1, 1a, 1b, 1c, 1c′, and 1d can add the third platform (not shown), the fourth platform or more platforms, such that the carriers 1, 1a, 1b, 1c, 1c′, and 1d can package more chips therein. Similarly, the number of the chips in the package module 3 and 3a is not limited. In addition, the type or size for the first chip 31, the second chip 32 and the third chip 33 is also not to be limited. The function or size of the first chip 31, the second chip 32 and the third chip 33 can be the same or the different.

According to aforementioned, the carriers 1, 1a, 1c, 1c′ and 1d and the substrates 2, 2a and 2b can be set via the standardization process and allow manufacturers other than packaging factory to manufacture, so as to the manufacturing cost can be reduced. In addition, the size of the packages can also be standardized by the standardized set. Thus, when the group of the stacked device 3 and 3a assembled to the carriers 1, 1a, 1b, 1c, 1c′, 1d with the alignment step, while the other components in the assembly is able to eliminate the aligning step, such that the use of packaging products and efficiency of packaging plants can be increased, and the modular setting can ensure the connection between the pads and the joints to increase the reliability. Also, because the group of stacked device 3 and 3a are placed in carriers 1, 1a, 1b, 1c, 1c′, and 1d such that the reliability of the package product can be improved.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A package module with an offset stacked device, comprising:
a carrier having a first surface and a second surface opposite said first surface, said first surface having a recess and an edge around said recess, such that a first chip arrangement region is formed in said recess and a plurality of metal connections is disposed on the bottom of said recess, said carrier having a platform which disposed adjacent to one side of said first chip arrangement region such that a recess wall is disposed between said platform and said first chip arrangement region and said plurality of metal connections is exposed, said platform is higher than said first chip arrangement region, said platform is disposed a plurality of second metal connections, wherein each said plurality of metal connections is electrically connected with each said plurality of second metal connections by a first metal wire.
a first chip having a top and a bottom and a plurality of first pads is disposed on said bottom of said first chip, said first chip is flipped on said first chip arrangement region and said plurality of first pads is electrically connected with said plurality of first metal connections;
a second chip having a top and a bottom and a plurality of second pads is disposed on said bottom of said second chip, said second chip is flipped on said top of said first chip such that said plurality of second pads is electrically connected with said plurality of second metal connections on said platform and portion of said top of said first chip is exposed;
a glue is filled in said recess of said carrier to encapsulate said top of said first chip and said top of said second chip;
wherein each said plurality of second metal connections is electrically connected with a plurality of second metal wires, said plurality of second metal wires is disposed from said platform of said carrier along said edge to extend on said second surface of said carrier, and a third metal connection is formed on one end of said second surface of each said second metal wires.

2. The package module with offset stacked device according to claim 1, said package module with the offset stacked device further comprising a substrate which having a third surface and a fourth surface opposites said third surface, and said substrate having a plurality of through holes that passed through from said third surface to said fourth surface, said third surface having a plurality of electric connections and said fourth surface having a plurality of outer connections, each said plurality of electric connections is passed through said plurality of through holes of said substrate extends to said fourth surface and is electrically connected with one of said plurality of outer connections, wherein said third surface of said substrate is stacked on said second surface of said carrier and each said plurality of electric connections is electrically connected with one of said plurality of third metal connections of said surface.

3. The package module with offset stacked device according to claim 1, wherein an angle is formed between said recess wall and said first chip arrangement region is range from 90 degree to 135 degree.

4. A package module with an offset stacked device, comprising:
a carrier having a first surface and a second surface opposites to said first surface, said first surface having a recess and an edge around said recess, a first chip arrangement region is disposed in said recess and a plurality of first metal connections is disposed on a bottom of said recess, a platform is disposed adjacent to one side of said first chip arrangement region such that a recess wall is formed between said platform and said first chip arrangement region and said plurality of first metal connections is exposed, and said platform is higher than said first chip arrangement region, a plurality of second metal connections is disposed on said platform, wherein each said plurality of first metal connections corresponding to one of said plurality of second metal connections and corresponding said first metal connection is electrically connected with said second metal connections by a first metal wire;
a first chip having a top and a bottom, and a plurality of first pads is disposed on said bottom of said first chip, said first chip is flipped on said first chip arrangement region such that said plurality of first pads is electrically connected with said plurality of first metal connections;
a second chip having a top and a bottom and a plurality of second pads is disposed on said bottom of said second chip, said second chip is flipped on said top of said first chip such that said plurality of second pads is electrically connected with said plurality of metal connections on said platform and portion said top of said first chip is exposed;
a glue is filled in said recess of said carrier to encapsulate said top of said first chip and said top of said second chip;
wherein portion of said plurality of first metal connections is electrically connected with a plurality of second metal wires and said plurality of second metal connections of remaining said plurality of first metal connections is electrically connected with a plurality of third metal wire, each said plurality of second metal wires extended from said first chip arrangement region to said edge, said plurality of metal wires on one end of said edge is to form a plurality of third metal connections, and each said plurality of metal wires extended from said platform to said edge and said plurality of third metal wire on one end of said edge is to form a plurality of fourth metal connections.

5. The package module with the offset stacked device according to claim 4, wherein said package module with the offset stacked device further comprising a substrate, said substrate having a third surface and a fourth surface opposite to said third surface, said substrate having a plurality of through holes and is passed through from said third surface to said fourth surface and said third surface having a plurality of electric connections and said fourth surface having a plurality of outer connections, each said plurality of electric connections is passed through said plurality of through holes of said substrate and extended to said fourth surface and is electrically connected with one of said plurality of outer connections, wherein said third surface of said substrate is stacked on said second surface of said carrier and each said plurality of electric connections is electrically connected with one of said plurality of third metal connections and said fourth metal connections on said second surface.

6. The package module with the offset stacked device according to claim 4, wherein an angle is formed between said recess wall and said first chip arrangement region which is in range from 90 degree to 135 degree.

7. A package module with an offset stacked device, comprising:
a carrier having a first surface and a second surface opposites to said first surface, and a plurality of carrier through holes is passed through said first surface to said second surface and said first surface having a recess and an edge around said recess, a first chip arrangement region is disposed on said recess and a plurality of first metal connections is disposed on a bottom of said recess, a platform is disposed adjacent to one side of said first chip arrangement region such that a recess wall is formed between said platform and said first chip arrangement region and said plurality of first metal connections is exposed, said platform is higher than said first chip arrangement region and a plurality of second metal connections is disposed on said platform;
a first chip having a top and a bottom, a plurality of first pads on said bottom of said first chip and said first chip is flipped on said first chip arrangement region such that said plurality of pads is electrically connected with said plurality of first metal connections;
a second chip having a top and a bottom and a plurality of second pads on said bottom of said second chip and said second chip is flipped on said top of said first chip such that said second plurality of pads is electrically connected with said plurality of second metal connections on said platform and said top of said first chip is exposed;
a glue is filled in said recess of said carrier to encapsulate said top of said first chip and said top of said second chip,
wherein said plurality of first metal connections and said plurality of metal connections are passed through said second surface of said carrier by said plurality of carrier through holes, and each said plurality of first metal connections and one end of each said plurality of second metal connections on said second surface is to be formed a third metal connections.

8. The package module with the offset stacked device according to claim 7, wherein said package module with said offset stacked device further comprising a substrate, said substrate having a third surface and a fourth surface opposite to said third surface, and said substrate having a plurality of through holes which is passed through said third surface to said fourth surface, said third surface having a plurality of electric connections and said fourth surface having a plurality of outer connections, each said plurality of electric connections is extended through said plurality of through holes to said surface and is electrically connected with one of said plurality of outer connections, wherein said third surface of said substrate is stacked on said second surface of said carrier and said plurality of electric connections is electrically connected with one of said plurality of third metal connections on said second surface.

9. The package module with the offset stacked device according to claim 7, wherein said package module with said offset stacked device further comprising a glue layer, said glue layer is disposed on said first surface of said carrier to encapsulate said first surface, said recess and said top of said second chip.

10. The package module with the offset stacked device according to claim 7, wherein an angle is formed between said recess wall and said first chip arrangement region which is in range from 90 degree to 135 degree.

11. A package module with an offset stacked device, comprising:
a carrier having a first surface and a second surface opposite to said first surface, and a plurality of carrier though holes is passed through said first surface to said second surface, a recess is disposed on said first surface and an edge around said recess, a first chip arrangement region is disposed on said recess and a plurality of first metal connections is disposed on a bottom of said recess, a platform is disposed adjacent to one side of said first chip arrangement region, such that a recess wall is formed between said platform and said first chip arrangement region and said plurality of first metal connections is exposed, said platform is higher than said first chip arrangement region, and a plurality of second metal connections is disposed on said platform, wherein each said plurality of metal connections is corresponding to one of said plurality of second metal connections and corresponded said plurality of first metal connections is electrically connected with said plurality of second metal connections by a metal wire;
a first chip having a top and a bottom and a plurality of first pads is disposed on said bottom of said first chip, and said first chip is flipped on said first chip arrangement region such that said plurality of first pads is electrically connected with said plurality of first metal connections;
a second chip having a top and a bottom and a plurality of second pads is disposed on said bottom of said second chip, said second chip is flipped on said top of said first chip, such that said plurality of second pads is electrically connected with said plurality of second metal connections on said platform and said top of said first chip is exposed; and
a glue is filled in said recess of said carrier to encapsulate said top of said first chip and said top of said second chip, wherein said plurality of first metal connections is extended to said second surface of said carrier through said plurality of carrier through holes and each said plurality of first metal connections on one end of said second surface is to form a third metal connection.

12. The package module with the offset stacked device according to claim 11, wherein said package module with said offset stacked device further comprising a substrate, said substrate having a third surface and a fourth surface opposite to said third surface, and said substrate having a plurality of through holes that is passed through from said third surface to said fourth surface, said third surface having a plurality of electric connections and said fourth surface having a plurality of outer connections, and each plurality of electric connections is extended to said fourth surface through said plurality of through holes and is electrically connected with one of said plurality of outer connections.

13. The package module with the offset stacked device according to claim 11, wherein said package module with said offset stacked device further comprising a glue, said glue is disposed on first surface of said carrier to encapsulate said first surface, said recess and said top of said second chip.

14. The package module with the offset stacked device according to claim 11, wherein an angle is formed between said recess wall and said first chip arrangement region which is in range from 90 degree to 135 degree.

15. A package module with an offset stacked device, comprising:
a carrier having a first surface and a second surface opposite to said first surface and a plurality of carrier through hole is passed through said first surface to said second surface, and a first recess is disposed on said first surface and an edge around said first recess, a first chip arrangement region is disposed in said first recess and a second recess is disposed in said first recess to form a controlling chip arrangement region, wherein said controlling chip arrangement region in said first chip arrangement region is disposed around said second recess is higher than said second recess and a plurality of first metal connections is disposed on said controlling chip arrangement region and a plurality of second metal connections is disposed on said first chip arrangement region and a platform is disposed adjacent to one side of said first chip arrangement region, such that a recess wall is formed between said platform and said first chip arrangement region and said plurality of second metal connections is exposed, and said platform is higher than said first chip arrangement region and said platform having a plurality of third metal connections thereon;
a controlling chip having a top and a bottom and a plurality of pads is disposed on said bottom of said controlling chip, said controlling chip is flipped on said controlling chip arrangement region such that said plurality of first pads is electrically connected with said plurality of first metal connections;
a first chip having a top and a bottom and a plurality of second pads on said bottom of said first chip, said first chip is flipped on said first chip arrangement region to encapsulate said controlling chip such that said plurality of second pads is electrically connected with said plurality of second metal connections;
a second chip having a top and a bottom and a plurality of third pads on said bottom of said second chip, said second chip is flipped on said top of said first chip such that said plurality of third pads is electrically connected with said plurality of third metal connections on said platform and portion said top of said first chip is exposed; and
a glue is filled in said recess of said carrier to encapsulate said top of said first chip and said top of said second chip,
wherein said plurality of first metal connections, said plurality of second metal connections and said plurality of third metal connections is extended to said second surface of said carrier through said plurality of carrier through holes, each said plurality of first metal connections, each said plurality of second metal connections and each said plurality of third metal connections on one end of said second surface is to form a third metal connection respectively.

16. The package module with the offset stacked device according to claim 15, wherein said package module with said offset stacked device further comprising a substrate, said substrate having a third surface and a fourth surface opposite to said third surface, and said substrate having a plurality of through holes that is passed through from said third surface to said fourth surface, said third surface having a plurality of electric connections and said fourth surface having a plurality of outer connections, each said plurality of electric connections is extended to said fourth surface through said plurality of through holes and is electrically connected with one of said plurality of outer connections, wherein said third surface of said substrate is stacked on said second surface of said carrier and each said plurality of electric connections is electrically connected with one of said plurality of fourth metal connections on said second surface.

17. The package module with the offset stacked device according to claim 15, wherein said package module with said offset stacked device further comprising a glue layer, said glue layer is disposed on said first surface of said carrier to encapsulate said first surface, said recess and said top of said second chip.

18. The package module with the offset stacked device according to claim 15, wherein an angle is formed between said recess wall and said first chip arrangement region which is in range from 90 degree to 135 degree.

19. A package module with an offset stacked device, comprising:
a carrier having a first surface and a second surface opposite to said first surface, said first surface having a recess and an edge around said recess, a first chip arrangement region is disposed on said recess, and a plurality of metal connections is disposed on a bottom of said recess, a platform is disposed adjacent to one side of said first chip arrangement region and said plurality of first metal connections is exposed and said platform is higher than said first chip arrangement region, and meanwhile, a first recess wall is formed between said platform and said first chip arrangement region and an angle is disposed between said first recess wall and said first chip arrangement region and is range from 90 degree to 135 degree, a third recess wall is disposed between said edge and said first chip arrangement region and an angle is disposed between said third recess wall and said first chip arrangement region which is in range from 90 degree to 135 degree, a plurality of second metal connections is disposed on said platform, wherein each said plurality of first metal connections is corresponding to said plurality of second metal connections, and corresponded said plurality of first metal connections is electrically connected with said plurality of second metal connections through a plurality of first metal wires and said plurality of first metal wires is disposed on said first recess wall;
a first chip having a top and a bottom and a plurality of second pads is disposed on said bottom of said first chip, said second chip is flipped on said top of said first chip such that said plurality of second pads is electrically connected with said plurality of second metal connections on said platform and said top of said first chip is exposed; and
a glue is filled in said recess of said carrier to encapsulate said top of exposed said first chip and said top of said second chip, wherein each said plurality of second metal connections is electrically connected with a plurality of second metal connections, said plurality of second metal connections is extended to said second surface of said carrier from said platform of said carrier to said second recess wall and said edge, and each said plurality of second metal connections on one end of said second surface is to form a third metal connection respectively.

20. The package module with the offset stacked device according to claim 19, wherein said package module with said offset stacked device further comprising a substrate, said substrate having a third surface and a fourth surface opposite to said third surface, said substrate having a plurality of through holes that is passed through said third surface to said fourth surface, said third surface having a plurality of electric connections and said fourth surface having a plurality of outer connections, each said plurality of electric connections is extended to said fourth surface through said plurality of through holes and is electrically connected with one of said plurality of outer connections, wherein said third surface of said substrate is stacked on said second surface of said carrier and each said plurality of electric connections is electrically connected with one of said plurality of third metal connections on said second surface, respectively.
